(19) United States
(12) Patent Application Publication
(10) Pub. No.: US 2016/0047936 A1
(43) Pub. Date: Feb. 18, 2016

(54) SYSTEMS AND METHODS FOR FORMATION EVALUATION USING MAGNETIC RESONANCE LOGGING MEASUREMENTS

(71) Applicant: SCHLUMBERGER TECHNOLOGY CORPORATION, Sugar Land, TX (US)

(72) Inventors: Mansoor Ali, Sugar Land, TX (US); Vivek Anand, Sugar Land, TX (US); Farid Hamichi, Sugar Land, TX (US)

(21) Appl. No.: 14/616,329

(22) Filed: Feb. 6, 2015

Related U.S. Application Data
(60) Provisional application No. 62/036,617, filed on Aug. 12, 2014.

(51) Int. Cl. G01V 3/32; G01R 33/38; G01R 33/56; G01R 33/48; G01R 33/561

(52) U.S. Cl. CPC G01V 3/32; G01R 33/4828; G01R 33/5615; G01R 33/5608; G01R 33/38

(57) ABSTRACT

A method for obtaining formation measurements. The method includes deriving a pulse sequence and magnetizing a formation by applying a static magnetic field, via a nuclear magnetic resonance (NMR) system, to the formation. The method further includes applying the pulse sequence by: a) measuring a first spin echo train after waiting a first time period; b) measuring at least two spin echo trains subsequent to the first spin echo train, where the at least two spin echo trains include a wait time shorter than the first time period; and c) repeating b at least two times. The method additionally includes determining a T1 and a T2 based on inversions of the measuring the first spin echo train, the measuring the at least two spin echo trains, or a combination thereof, to determine a formation measurement.

### CROSS-REFERENCE TO RELATED APPLICATIONS

This application claims the benefit of related U.S. Provisional Application Ser. No. 62/036,617, filed on Aug. 12, 2014, the disclosure of which is incorporated by reference herein in its entirety.

### BACKGROUND

This disclosure relates to methods for the evaluation of formations using magnetic resonance measurements.

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light, and not as admissions of any kind.

Both water and hydrocarbons in earth formations produce detectable nuclear magnetic resonance (NMR) signals. It is desirable that the signals from water and hydrocarbons be separable so that hydrocarbon-bearing zones may be identified. However, it may not be easy to distinguish which signals are from water and which are from hydrocarbons. For example, while NMR logging is becoming increasingly important for formation evaluation in “unconventional” formations, particularly shale formations, current NMR techniques may not provide certain desired results. For example, T2 (e.g., spin-spin relaxation) time distributions may be used for predicting movable and effective porosity in shale formations by applying core-derived cutoffs. However, estimations based on a derived fluid saturation measure derived by partitioning the T2 distributions may not be as useful because a response of formation fluids (e.g., water, oil, gas and bitumen) may overlap in the T2 domain. Thus, the application of two-dimensional D-T2 derivations for estimation of fluid saturations may not be as accurate in shale reservoirs because of very fast T2 relaxation of fluids in the nanometer sized pores. It would be beneficial to improve certain NMR derivations.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be explicitly set forth below.

One or more embodiments of the disclosure relate to well-logging using nuclear magnetic resonance (NMR) systems. According to one aspect of the disclosed subject matter, a method is described for obtaining formation measurements. The method includes deriving a pulse sequence and magnetizing a formation by applying a static magnetic field, via a nuclear magnetic resonance (NMR) system, to the formation. The method further includes applying the pulse sequence by: a) measuring a first spin echo train after waiting a first time period; b) measuring at least two spin echo trains subsequent to the first spin echo train, where the at least two spin echo trains include a wait time shorter than the first time period; and c) repeating b at least two times. The method additionally includes determining a T1 and a T2 (e.g., T1 and T2 distributions) based on inversions of the measuring the first spin echo train, the measuring the at least two spin echo trains, or a combination thereof, to determine a formation measurement.

In another example, a system includes a processor. The processor is configured to derive a pulse sequence, and to magnetize a formation by applying a static magnetic field to the formation. The processor is further configured to apply the pulse sequence by: a) measuring a first spin echo train after waiting a first time period; and b) measuring at least two spin echo trains subsequent to the first spin echo train, where the at least two spin echo trains include a wait time shorter than the first time period. The processor is further configured to determine at least one T1 and at least one T2 based on inversions of the measuring the first spin echo train, the measuring the at least two spin echo trains, or a combination thereof, to determine a formation measurement.

The system is more particularly configured to carry out one or more of the embodiments of the method as disclosed hereafter.

Moreover, a non-transitory, tangible computer readable storage medium, comprising instructions is described. The instructions are configured to derive a pulse sequence and to magnetize a formation by applying a static magnetic field, via a nuclear magnetic resonance (NMR) system, to the formation. The instructions are additionally configured to apply the pulse sequence by: a) measuring a first spin echo train after waiting a first time period, and b) measuring at least two spin echo trains subsequent to the first spin echo train, where the at least two spin echo trains include a wait time shorter than the first time period. The instructions are further configured to determine a T1 and a T2 based on inversions of the measuring the first spin echo train, the measuring the at least two spin echo trains, or a combination thereof, to determine a formation measurement.

Various refinements of the features noted above may be undertaken in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings in which:

FIG. 1 is a diagram of a downhole nuclear magnetic resonance (NMR) data acquisition system, in accordance with an embodiment;

FIG. 2 is a more detailed diagram of the system of FIG. 1, in accordance with an embodiment;

FIG. 3 is a timing diagram of a pulse sequence that may be employed by the NMR data acquisition system of FIGS. 1 and 2, in accordance with an embodiment; and

FIG. 4 is a chart of certain data that may be acquired using the pulse sequence of FIG. 3;

FIG. 5 is an embodiment of a T1T2 map that may be visualized using the techniques described herein;

FIG. 6 is an embodiment of a second T1T2 map that may be visualized using the techniques described herein;

FIG. 7 is a flowchart of an embodiment of a process suitable for more accurately deriving certain formation measurements;

FIG. 8 illustrates an embodiment of a chart useful in deriving T1 and T2;

FIG. 9 depicts embodiments of spin echo trains useful in deriving T1 and T2; and

FIG. 10 is a cross-section view of an embodiment of a Combinable Magnetic Resonance (CMR) device suitable for providing more accurate NMR measurements.

### DETAILED DESCRIPTION

The disclosed subject matter describes an improved nuclear magnetic resonance (NMR) pulse sequence suitable for downhole measurement of T1 and T2 distributions in unconventional formations such as shale formations. T1 data may include a spin-lattice relaxation time, for example, for a longitudinal (e.g., spin-lattice) recovery of a z component of nuclear spin magnetization due to NMR excitation. T2 data may include a spin-spin relaxation time, for example, for a transverse (e.g., spin-spin) relaxation of an XY component of nuclear spin magnetization due to the NMR excitation. The pulse sequence may be implemented on a variety of NMR systems described herein, including Combinable Magnetic Resonance (CMR) systems, with relatively minor firmware updates applying changes to executable code. In certain embodiments, T1/T2 ratios may be used to estimate fluid saturations in unconventional formations with improved accuracy. A basis of an improved estimation is a T1/T2 ratio contrast between hydrocarbons and water. The T1/T2 ratio of oil, for example, is found to be much higher than that for water. Accordingly, oil and water peaks are more clearly distinguishable between each other when T1, T2 are applied (e.g., T1/T2 ratio, T1T2 maps, and the like). “Short” T1 and/or T2 measurements may be used, which may result in enhanced accuracy and may increase observational detail, as described in more detail below. Likewise, an enhanced pulse sequence may be used, which may additionally improve faster data acquisition and accuracy.

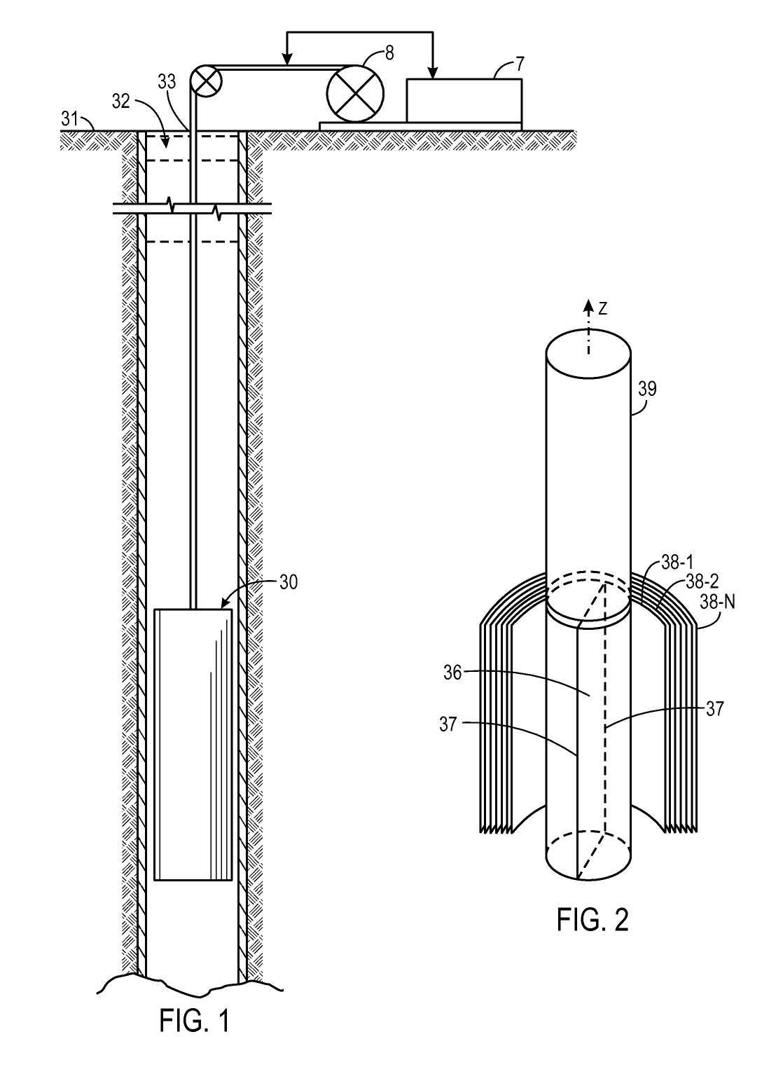

Acquisition of NMR and other measurements according to one or more embodiments described herein may be accomplished using any suitable techniques for obtaining NMR measurements and other downhole measurements. For example, the measurements may be performed in a laboratory or in the field using a sample removed from an earth formation. Additionally or alternatively, the NMR and other measurements may be performed in a logging operation using any suitable downhole tool (e.g., a wireline tool, a logging-while-drilling and/or measurement-while-drilling tool, and/or a formation tester). FIG. 1 illustrates a schematic of an embodiment of an NMR logging system. In FIG. 1, an NMR logging tool 30 that may investigate earth formations 31 traversed by a borehole 32 is shown. The NMR logging device 30 is suspended in the borehole 32 on a cable 33 (e.g., an armored cable), the length of which may determine the relative axial depth of the device 30. The cable length may be controlled by any suitable surface winch, such as a drum and winch mechanism 8. Surface equipment 7 may be of any suitable type and may include a processor subsystem (e.g., a processor, memory, and/or storage) that communicates with downhole equipment including NMR logging device 30. The techniques of this disclosure may be carried out by the processor subsystem at the surface and/or by a processor subsystem associated with the NMR logging device 30 downhole.

The NMR logging device 30 may be any suitable nuclear magnetic resonance logging device; it may be one for use in wireline logging applications, or one that can be used in logging-while-drilling (LWD) or measurement-while-drilling (MWD) applications. Additionally or alternatively, the NMR logging device 30 may be part of any formation tester known in the art, such as that sold under the trade name of MDT™ by Schlumberger Limited, of Houston, Tex. The NMR logging device 30 may include a permanent magnet or magnet array that produces a static magnetic field in the formation, and a radio frequency (RF) antenna to produce pulses of magnetic field in the formations and to receive resulting spin echoes from the formations.

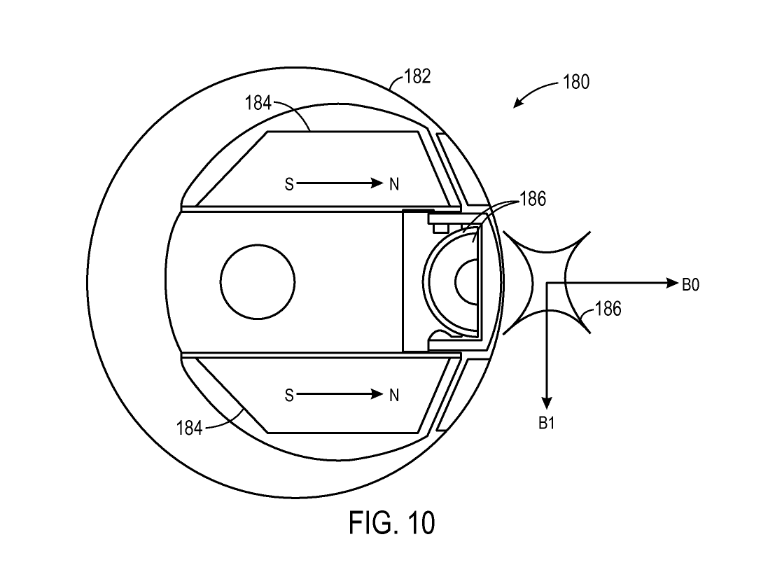

FIG. 2 illustrates a schematic of some of the components of one type of NMR logging device 30, such as a general representation of closely spaced cylindrical thin shells, 38-1, 38-2 . . . 38-N, which may be frequency-selected in a multi-frequency logging operation. One such device is disclosed in U.S. Pat. No. 4,710,713. In FIG. 2, another magnet or magnet array 39 is shown. Magnet array 39 may be used to pre-polarize the earth formation ahead of the investigation region as the logging device 30 is raised in the borehole in the direction of arrow Z. Examples of such devices are disclosed in U.S. Pat. Nos. 5,055,788 and 3,597,681. It is to be noted that NMR data, such as logging data, may be captured from any suitable number of NMR systems, including Combinable Magnetic Resonance (CMR) systems (e.g. as described in FIG. 10) Magnetic Resonance Imager Log (MRIL) systems, Magnetic Resonance scanners, and the like. The tool 30 may thus provide data representative of T1 and T2, useful in estimating volumetric measurements of the formation.

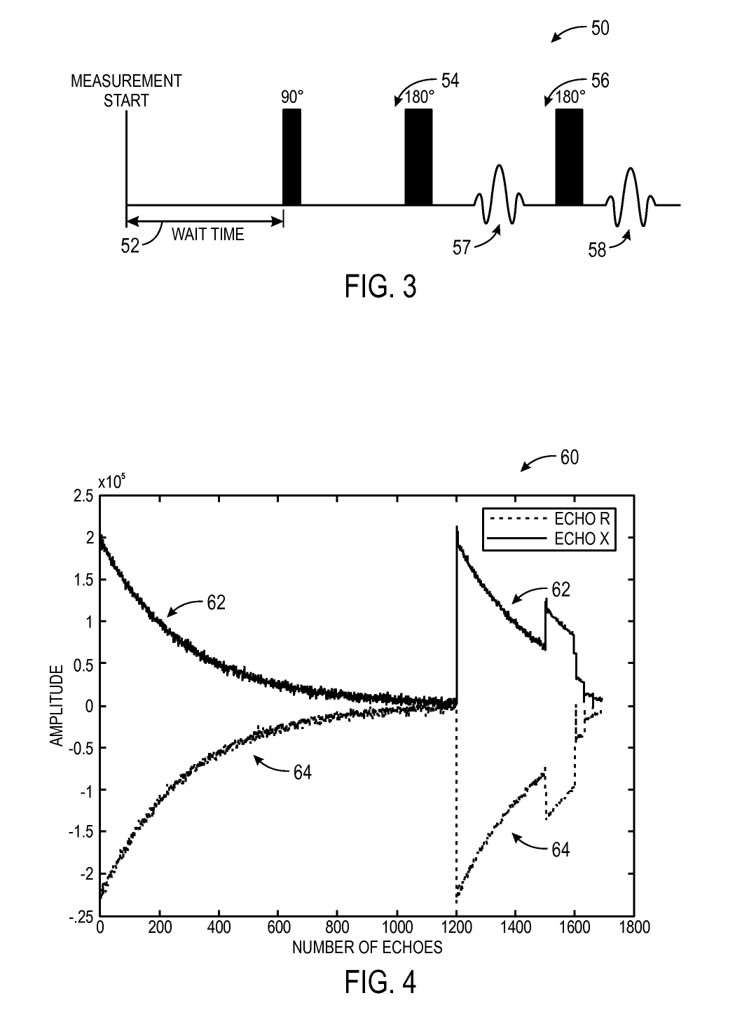

FIG. 3 depicts an embodiment of an enhanced pulse sequence 50 that may be employed by the NMR systems described with respect to FIGS. 1, 2 and 10, to more accurately derive certain formation measurements. For example, the pulse sequence 50 may be used to more accurately derive fluid saturations, for example, in unconventional formations such as shale formations. In one embodiment, the pulse sequence 50 may be used for continuous T1/T2 measurement as a saturation recovery sequence. The pulse sequence 50 may include multiple Carr-Purcell-Meiboom-Gill (CPMG) echo trains with varying wait times 52, as shown. Accordingly, an inversion recovery sequence is not recommended because the inversion recovery sequence may take much longer to complete, and may involve more substantial changes in firmware. By way of contrast, a saturation recovery sequence may involve lesser measurement time and may be implemented in firmware with relatively minor changes.

The saturation recovery sequence proposed for NMR systems (e.g., CMR systems) comprises 6 sub-measurements with varying wait time 52, where a sub-measurement is defined as the CPMG echo train with unique sequence parameters. The first sub-measurement is acquired with the longest wait time in the sequence and shortest possible echo spacing (e.g., time between leading edge of a rectangle illustrated and leading edge of a subsequent rectangle), such as spacing 54, 56. The first sub-measurement generally may serve two purposes. First, a sub-measurement with long wait time may transmit the echoes acquired during the entire sequence. Second, long wait time may result in complete polarization and therefore may help in constraining the inversion. The saturation recovery sequence uses a magnetization that is saturated (i.e. destroyed) before the beginning of each sub measurement. If the measurement tool (e.g., NMR system of FIGS. 1, 2, 10 or components thereof) moves during the acquisition of the echo train, the antenna may enter a region with significant pre-polarization. To saturate the magnetization, a set of crusher pulses may then be applied after the sub-measurement with the longest wait time.

The first sub-measurement may then be followed by, for example, 5 sub-measurements of varying wait times in increasing order. It should be noted, that the sub-measurements of varying wait times may be less or more than 5 sub-measurements, and may additionally be in decreasing order, or in a combination of increasing and decreasing order. The number of echoes 57, 58 acquired during each sub-measurement is increased proportionately with the wait time. Note that this may avoid crusher pulses for the subsequent sub-measurements because the measurement time for these echo trains is quite short and tool motion would have little effect.

In one CMR embodiment, example, there are at least three preferences that the enhanced pulse sequences described herein may fulfill. It is to be understood, that in other NMR system embodiments, pulse sequence may be used that include different properties, such as number of echoes, duty cycles, logging speed, and the like, suitable for applying the T1, T2 techniques described herein.

1. Number of Echoes:

One of the preferences for the firmware is that there be a minimum 4 ms time duration (excluding the wait time) between each echo train to load the parameters for the next echo train. Specifically, the following constraint may be met: (NECH−2)·TE>4 ms where NECH and TE are the number of echoes and echo spacing for the echo train. This constraint may determine the minimum number of echoes in each echo train.

2. Duty Cycle:

A transmitter duty cycle for an echo train is defined as the ratio of time during which a transmitter RF pulses are on to the total measurement time (including the wait time). One duty cycle for a measurement may be less than 5%.

3. Logging Speed

A measurement time for the T1/T2 pulse sequence 50 may be considerable longer compared to a T2-based logging. The measurement time thus may be optimized such that a reasonable logging speed (upwards of 240 ft./hr.) may be achieved.

It may be beneficial to show some example pulse train values, accordingly Table 1 shows example parameter ranges for the T1/T2 pulse sequence 50. The sequence 50 based on certain of the parameters of Table 1 fulfills the above-mentioned preferences. The number of echoes for each sub-measurement is chosen such that the requirement for minimum acquisition time of 4 ms is fulfilled. The average duty cycle of the sequence is 1.5%, which is lower than the desired limit of 5%. Finally, the sequence takes 5.7 sec to complete. Based on a 12-inch sampling rate, a logging speed of 300 ft./hr. could be achieved. The sequence 50, however, could accurately resolve T1 times shorter than 1 second (which is mostly the case in shale formations). If longer T1 relaxation times are to be measured, the pulse sequence 50 may be modified. It is to be noted that the ranges shown in Table 1 are examples only, and that the values calculated for number of echoes, duty cycle, and logging speed above may be different based on selecting a specific number or numbers.

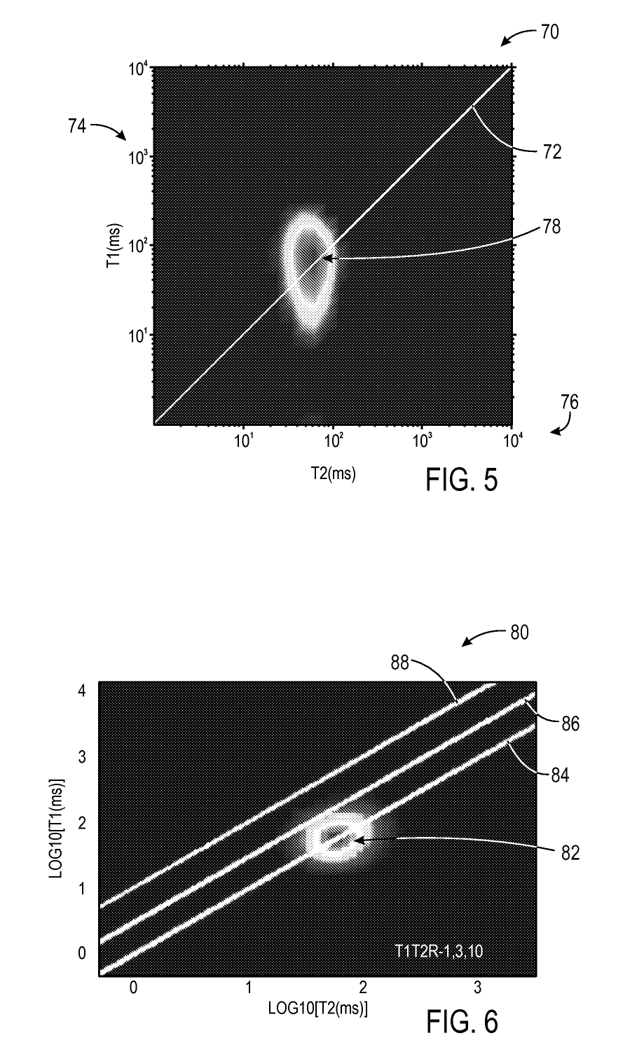

TABLE 1
Parameters for the proposed T1/T2 pulse sequence

| | | | |
|---|---|---|---|
| Sub | WT | TE | ECHO train |

| Measure | ms | ms | NECHO | NRPT |
|---|---|---|---|---|
| 1 | 2000-5000 | 0.05-0.4 | 1000-3000 | 1-5 |
| 2 | 200-500 | 0.05-0.4 | 100-500 | 1-5 |
| 3 | 25-100 | 0.05-0.4 | 50-200 | 5-20 |
| 4 | 5-20 | 0.05-0.4 | 30-75 | 15-50 |
| 5 | 1-6 | 0.05-0.4 | 10-30 | 30-75 |
| 6 | 1-6 | 0.05-0.4 | 10-30 | 30-75 |

Where WT is wait time, TE is the echo spacing, NECHO is the number of echoes, and NRPT is the number of repetitions. It is to be noted that Table 1 above is one example, and other parameters may be used, suitable for defining the pulse sequence 50 in view of the desired three preferences (e.g., number of echoes, duty cycle, and logging speed). To validate the feasibility of T1/T2 logging measurement with a nuclear magnetic resonance (NMR) and/or combinable magnetic resonance (CMR) system and corresponding electronics, the T1/T2 pulse sequence may be programmed, for example in a CMR tool shown in FIG. 10. The programmed pulse sequence 50 may include 6 wait times (or more) with the shortest wait time equal to approximately less than 3 milliseconds. The shorter wait time may thus provide for increased accuracy and more precise measurements. Minor changes may be made to firmware, such as a dynamic link library (DLL), to enable operation of the new pulse sequence 50 and corresponding data acquisition. FIG. 4 shows a chart 60 of data that may be acquired using the T1/T2 pulse sequence 50 with doped water (doped with NiCl2) as a test. The test validates that it is useful to operate via a T1/T2 pulse sequence with 6 sub-measurements in a depth logging mode with, for example, NMR systems such as the CMR tool of FIG. 10. Furthermore, the test also proves that it is possible to achieve a short wait time, such as a wait time of 3 ms or less. The figure shows two orthogonal channels 62, 64. The data in chart 60, including channels 62, 64 may then be used to derive a T1T2 map 70, as shown in FIG. 5.

More specifically, the T1T2 map 70 of FIG. 5 shows that a measured T1/T2 ratio 72 is close to 1, as expected for water doped with NiCl2. As shown, the map 70 may be produced by combining T1's 74 with T2's 76 (e.g., T1/T2) to derive observations such as a water peak 78, useful in estimating volumes of formations. In another example, shown in FIG. 6, a T1T2 map 80 is depicted. Echo data may be processed to obtain high-resolution one or two dimensional relaxation time distribution maps, as shown in the T1T2 map 80. More specifically, FIG. 6 shows a high resolution 2D view of the T1T2 map 80 of water (e.g., waters disposed in a geologic sample, such as a rock sample) from inversion of the echo data. It is to be understood that the techniques described herein may obtain a one dimensional T1 distribution, a one dimensional T2 distribution, or a combination thereof. Likewise, the techniques described herein may obtain combinations of one and two dimensional T1 and T2 derivations. A water peak 82 may also clearly be observed. Lines 84, 86, and 88 representative of corresponding T1/T2 ratios 1, 3, and 10 are also depicted. Again, the test depicted in the T1T2 map 80 validates the use of T1/T2 ratios for volumetric observation of formations.

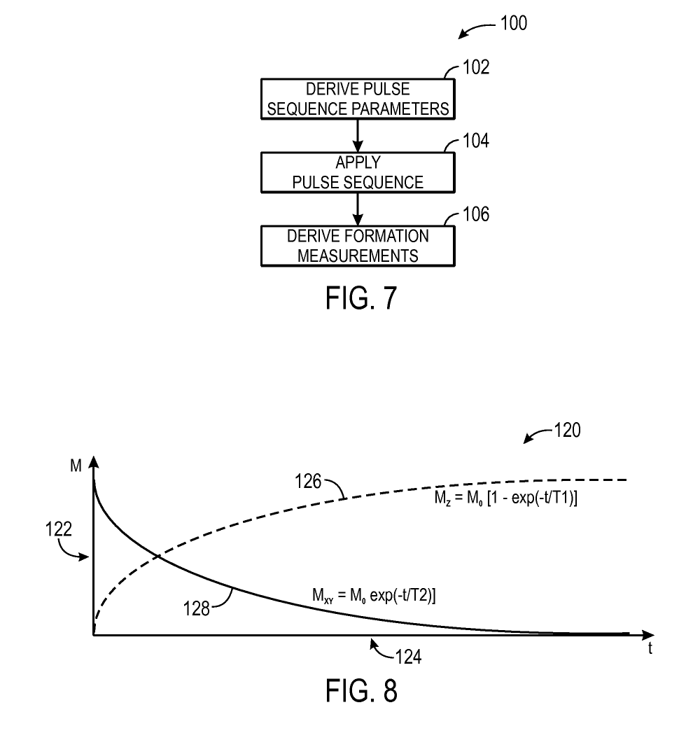

Turning now to FIG. 7, the figure is a flow chart of an embodiment of a process 100 suitable for more accurately deriving unconventional formation measurements via the pulse sequence 50 of FIG. 3. The process 100 may be executed via hardware processor included in the NMR system described with respect to FIGS. 1, 2, and 10. In the depicted embodiment, the process 50 may derive certain parameters (block 102) defining the pulse sequence 50, for example, as described above with respect to Table 1. That is, parameters such as the number of sub-measurements may be defined (e.g., 6), and for each sub-measurement a wait time, an echo spacing, a number of echoes, a number of repetitions, and the like, may also be defined. As mentioned earlier, the parameters may include three preferences based on number of echoes, duty cycle, and logging speed. The parameters may be pre-derived and stored as one or more tables stored in a memory of the NMR system, such as the system of FIGS. 1, 2, and 10.

The process 100 may apply the pulse sequence 50 (block 104) when analyzing a formation such as the formation 31. For example, the process 100 may execute the pulse sequence 50 to include multiple echo trains with varying wait times by applying a static magnetic field, via a NMR system, to the formation 31. For example, six sub-measurements may be derived, the first sub-measurement followed by 5 sub-measurements of varying wait times in increasing order. Once the pulse sequence 50 has been applied, T1 and T2 may be used to derive one or more measurements (block 106), such as volumetric formation characterization measurements. The measurements may include T1 and T2 derivations, which may then be used to create T1T2 maps 70, 80 that more accurately measure formations, including fluid saturations in shale formations.

It may be useful to describe derivations of the T1 and T2 measurements. Accordingly, FIG. 8 illustrates embodiments of T1 and T2 measurements that may be derived using the techniques described herein. More specifically, FIG. 8 shows a graph 120 having an abscissa axis 122 representative of magnetization (M) and an ordinal axis 124 representative of time. A pulse train, such as a Car-Purcell-Meiboom-Gill (CPMG) may result in radio frequency pulses delivered to the formation 31, which may lead to echo formation. The acquired echoes may be directly related to T2 processes. In the depicted embodiment, a curve 128 may be indicative of relaxation of M over time with the equation

$${M}_{xy} = {M}_{0} exp ( - \frac{t}{T 2} ) .$$

T1 may be defined based on curve 126 where

$${M}_{z} = {M}_{0} [ 1 - exp ( - \frac{t}{T 1} ) ] .$$

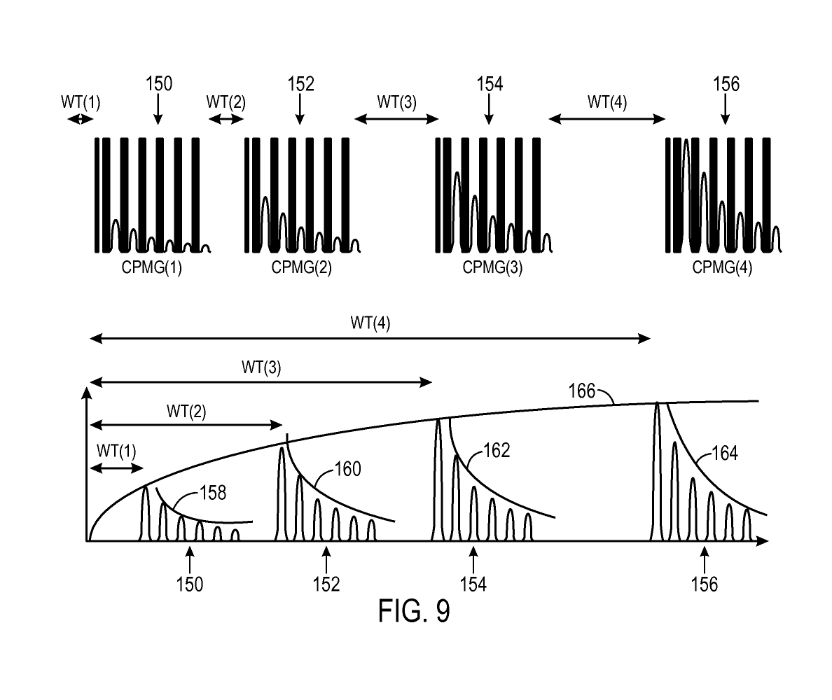

Accordingly, data processing may derive T2 and T1 based on acquired echoes. For example, embodiments of spin echo trains 150, 152, 154, 156 and correlative CPMG pulses (shown as horizontal bars adjacent to the echoes) depicted in FIG. 9, may be analyzed to derive T2, T1.

As shown in FIG. 9, the spin echo trains 150, 152, 154, 156 are separated by wait times (WT) such that each successive wait time is longer than the previous wait time. However, it is to be noted that in other embodiments, successive wait times may be the same, may be shorter, or a combination thereof. Indeed, in one embodiment, the wait times between pulse trains may get successively shorter. To derive T2, echo decay curves 158, 160, 162, 164 derived from corresponding set of echo peaks, may be used. Each of the echo decay curves 158, 160, 162, 164 may follow a geometry or shape corresponding to curve 128 of FIG. 8, and thus may provide information suitable for derivation of one T2 measurement for each of the echo decay curves 158, 160, 162, 164. T1 may be derived by using a first peak of each of the spin echo trains 150, 152, 154, 156 to build a curve 166. Curve 166 may include a geometry or shape similar to curve 126 of FIG. 8, and may thus be used to estimate T1. While only four spin echo trains 150, 152, 154, 156 are depicted, it is to be understood that more spin echo trains may be used to improve accuracy of derivation. With T2 and T1 derived, T1T2 maps may be derived, with desired T1/T2 ratios as shown earlier in FIGS. 4 and 5. Additionally, as described in more detail below with respect to FIG. 10, an enhanced T1/T2 having, for example, a “short” T2 and a “short” T1 may be used to derive more accurate T1/T2 measurements.

In one example, the short T2 may include T2 having between 0.1 and 3 milliseconds or more. The enhanced T1/T2 derivation incorporating the short T2 may thus be able to more accurately measure a volume, for example, when compared to using longer T2's. FIG. 10 is a top cross-sectional view of an embodiment of a Combinable Magnetic Resonance (CMR) tool 180 shown disposed inside of a bore wall 182 that may be used to derive the enhanced T1, T2 measurements. The CMR tool 120 may include memory suitable for storing executable instructions or computer code, which may be executed in one or more processors of the CMR tool 180. An example CMR tool 180 is available under the trade name of CMR-Plus™ by Schlumberger Limited, of Houston, Tex. The CMR tool 180 may use the pulse acquisition sequence techniques described herein, which may improve the precision of the data associated, for example with small pore heavy crude oils. The CMR tool 180 may include two permanent magnets 184, and a RF antenna 186, suitable for NMR measurements. In particular, the antenna may more accurately measure an area of interest 188 via the pulse acquisition sequences described herein. Accordingly, the T1/T2 ratio may more accurately derive volumes for heavy oil, bitumen, clay-bound water (CBW), and the like. Applying the enhanced T1/T2 may thus provide for more accurate measurements of formation compositions. Indeed, by applying T1/T2 as described herein, a more accurate and efficient derivation of volumetric information for a variety of formations, including shales, may be achieved.

Although only a few example embodiments have been described in detail above, those skilled in the art will readily appreciate that many modifications are possible in the example embodiments without materially departing from “Systems and Methods for Formation Evaluation Using Magnetic Resonance Logging Measurements.” Features shown in individual embodiments referred to above may be used together in combinations other than those which have been shown and described specifically. Accordingly, all such modifications are intended to be included within the scope of this disclosure. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. §112, paragraph 6 for any limitations of the any of the claims herein, except for those in which the claim expressly uses the words ‘means for’ together with an associated function.

What is claimed is:

1. A method for obtaining formation measurements, the method comprising:
deriving a pulse sequence;
magnetizing a formation by applying a static magnetic field, via a nuclear magnetic resonance (NMR) system, to the formation;
applying the pulse sequence by:
a) measuring a first spin echo train after waiting a first time period;
b) measuring at least two spin echo trains subsequent to the first spin echo train, where the at least two spin echo trains include a wait time shorter than the first time period; and
c) repeating b at least two times; and
determining a T1 and a T2 based on inversions of the measuring the first spin echo train, the measuring the at least two spin echo trains, or a combination thereof, to determine a formation measurement.

2. The method of claim 1, comprising deriving the pulse sequence by deriving a number of echoes, a duty cycle, and a logging speed.

3. The method of claim 1, comprising deriving a T1T2 map based on a T1/T2 ratio to determine the formation measurement.

4. The method of claim 3, wherein deriving the T1T2 map comprises using a short T2 of less than 3 milliseconds.

5. The method of claim 3, wherein the T1/T2 ratio is between 0.5 and 10.

6. The method of claim 1, wherein deriving the pulse sequence comprises deriving at least 6 sub-measurements.

7. The method of claim 6, wherein the at least six sub-measurements are stored in a memory of the NMR system to be used for applying the pulse sequence.

8. The method of claim 1, wherein the formation comprises an unconventional formation.

9. A nuclear magnetic resonance (NMR) system, comprising:
a processor configured to:
derive a pulse sequence;
magnetize a formation by applying a static magnetic field to the formation;
apply the pulse sequence by:
a) measuring a first spin echo train after waiting a first time period;
b) measuring at least two spin echo trains subsequent to the first spin echo train, where the at least two spin echo trains include a wait time shorter than the first time period; and
determine at least one T2 based on inversions of the measuring the first spin echo train, the measuring the at least two spin echo trains, or a combination thereof, to determine a formation measurement.

10. The system of claim 9, wherein the processor is configured to derive the pulse sequence by deriving a number of echoes, a duty cycle, and a logging speed.

11. The system of claim 9, wherein the processor is configured to derive a plurality of T2s, and to derive one T1 based on one or more of the plurality of T2s.

12. The system of claim 9, wherein the at least one T2 comprises a short T2 having a time of less than 3 milliseconds, and wherein processor is configured to derive a T1T2 map by using the short T2.

13. The system of claim 9, wherein the processor is configured to derive the pulse sequence by deriving at least six sub-measurements.

14. The system of claim 13, comprising a memory, wherein the at least six sub-measurements are stored in the memory to be used by the processor for applying the pulse sequence.

15. The system of claim 9, wherein the processor is included in a Combinable Magnetic Resonance (CMR) system.

16. A non-transitory, tangible computer readable storage medium, comprising instructions configured to:
derive a pulse sequence;
magnetize a formation by applying a static magnetic field, via a nuclear magnetic resonance (NMR) system, to the formation;
apply the pulse sequence by:
a) measuring a first spin echo train after waiting a first time period;
b) measuring at least two spin echo trains subsequent to the first spin echo train, where the at least two spin echo trains include a wait time shorter than the first time period; and
determine a T1 and a T2 based on inversions of the measuring the first spin echo train, the measuring the at least two spin echo trains, or a combination thereof, to determine a formation measurement.

17. The storage medium of claim 16, comprising instructions to derive a T1T2 map to determine the formation measurement.

18. The storage medium of claim 16, wherein the formation measurement comprises a volume.

19. The storage medium of claim 16, comprising instructions to repeat b at least two times.

20. The storage medium of claim 16, wherein the formation measurement is determined using a T1/T2 ratio between 0.5 and 10.
